(19) United States
(12) Patent Application Publication
(10) Pub. No.: US 2026/0150458 A1
(43) Pub. Date: May 28, 2026

(54) Display Apparatus Having Light-Emitting Devices and Pixel Lenses

(71) Applicant: LG Display Co., Ltd., Seoul (KR)

(72) Inventors: Bo A Jin, Paju-si (KR); Jung Mo Cho, Paju-si (KR)

(21) Appl. No.: 19/326,109

(22) Filed: Sep. 11, 2025

(30) Foreign Application Priority Data
Nov. 25, 2024 (KR) 10-2024-0169743

(51) Int. Cl. H10H 29/34; H10H 20/813; H10H 20/851; H10H 20/855; H10H 29/37; H10H 29/39

(52) U.S. Cl. CPC H10H 29/345; H10H 20/8131; H10H 20/8512; H10H 20/855; H10H 29/37; H10H 29/39

(57) ABSTRACT

A display apparatus including light-emitting devices and pixel lenses is disclosed. The light-emitting devices and the pixel lenses are on emission areas of a device substrate. The emission areas can include a first emission area and a second emission area having a planar shape different from the first emission area. The pixel lenses include a first pixel lens having a planar shape corresponding to the first emission area and a second pixel lens having a planar shape corresponding to the second emission area. The light-emitting devices can include a first light-emitting device and a second light-emitting device. The second emission area can display a same color as the first emission area. Light emitted from the second light-emitting device can have different characteristics from light emitted from the first light-emitting device. Thus, in the display apparatus, the overall lifespan can be increased.

### CROSS-REFERENCE TO RELATED APPLICATION

This application claims the benefit of Republic of Korea Patent Application No. 10-2024-0169743, filed on Nov. 25, 2024, which is hereby incorporated by reference in its entirety.

### BACKGROUND

### Field of Technology

The present disclosure relates to a display apparatus in which a light-emitting device and a pixel lens are stacked on each emission area of a device substrate.

### Discussion of the Related Art

Generally, a display apparatus provides an image to a user. For example, the display apparatus can include light-emitting devices. Each of the light-emitting devices can emit light displaying a specific color. For example, each of the light-emitting devices can include a light-emitting unit between a lower electrode and an upper electrode. Pixel lenses can be disposed on the light-emitting devices. Light emitted from each light-emitting device can be focused by one of the pixel lenses. For example, each of the pixel lenses can overlap one of the light-emitting devices.

### SUMMARY

Accordingly, the present disclosure is directed to a display apparatus that substantially obviates one or more problems due to limitations and disadvantages of the related art.

An object of the present disclosure is to provide a display apparatus capable of increasing the overall lifespan of the display device.

Another object of the present disclosure is to provide a display apparatus capable of minimizing the variation in the quality of images having different viewing angles according to usage time.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising: a first light-emitting device on a first emission area of a device substrate; a second light-emitting device on a second emission area of the device substrate, the second light-emitting device emitting light of a same color as the light emitted by the first light-emitting device; a first pixel lens on the first light-emitting device, the first pixel lens having a planar shape corresponding to a planar shape of the first emission area; and a second pixel lens on the second light-emitting device, the second pixel lens having a planar shape corresponding a planar shape of the second emission area, wherein the planar shape of the second emission area is different from the planar shape of the first emission area, and wherein an electroluminescence spectrum of the light emitted by the second light-emitting device is different from an electroluminescence spectrum of the light emitted by the first light-emitting device.

In one embodiment, a display apparatus comprises: a device substrate; a bank insulating layer on the device substrate, the bank insulating layer defining a first emission area and a second emission area in a sub-pixel; an optical insulating layer on the bank insulating layer, the optical insulating layer overlapping the first emission area and the second emission area; a first light-emitting device between the device substrate and the optical insulating layer in the first emission area, the first light-emitting device including a first light-emitting unit; a second light-emitting device between the device substrate and the optical insulating layer in the second emission area, the second light-emitting device including a second light-emitting unit; a first pixel lens on the optical insulating layer, the first pixel lens overlapping the first light-emitting device; and a second pixel lens on the optical insulating layer, the second pixel lens overlapping the second light-emitting device, wherein a planar shape of the second pixel lens is different from a planar shape of the first pixel lens, wherein a stacked structure of the second light-emitting unit is a same as a stacked structure of the first light-emitting unit, and wherein at least one layer of layers constituting the second light-emitting unit has a composition ratio that is different from a corresponding layer of the first light-emitting unit.

In one embodiment, a display device comprises: a device substrate including a sub-pixel, the sub-pixel having a first emission area and a second emission area; a driving transistor; a first light-emitting device on the first emission area, the first light-emitting device connected to the driving transistor; a second light-emitting device on the second emission area and connected to the driving transistor, the second light-emitting device emitting light of a same color of light emitted by the first light-emitting device but having an electroluminescence spectrum that is different from an electroluminescence spectrum of the light emitted by the first light-emitting device; a first pixel lens overlapping the first light-emitting device in the first emission area; and a second pixel lens overlapping the second light-emitting device in the second emission area, wherein the display device displays an image having a first viewing angle during a first mode during which the first light-emitting device emits the light through the first pixel lens, and the display device displays an image having a second viewing angle that is different from the first viewing angle during a second mode during which the second light-emitting device emits the light through the second pixel lens.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a location where a display panel of a display apparatus according to an embodiment of the present disclosure is installed;

FIG. 2 is an enlarged view of a pixel area in the display apparatus according to an embodiment of the present disclosure;

FIG. 3 is a view showing a circuit of a sub-pixel in the display apparatus according to an embodiment of the present disclosure;

FIG. 4 is a view taken along I-I′ and II-II′ of FIG. 2 according to an embodiment of the present disclosure;

FIG. 5 is an enlarged view of K1 region and K2 region in FIG. 4 according to an embodiment of the present disclosure;

FIG. 6 is a graph showing simulation results for an electroluminescence (EL) spectrum of a first green light emitted from the light-emitting device including a green fluorescent dopant and an EL spectrum of a second green light emitted from the light-emitting device including a green phosphorescent dopant according to an embodiment of the present disclosure.

FIG. 7 is a graph showing simulation results for a relative luminance according to usage time of the first green light emitted from the light-emitting device including a green fluorescent dopant and the second green light emitted from the light-emitting device including a green phosphorescent dopant according to an embodiment of the present disclosure; and

FIGS. 8 to 14 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

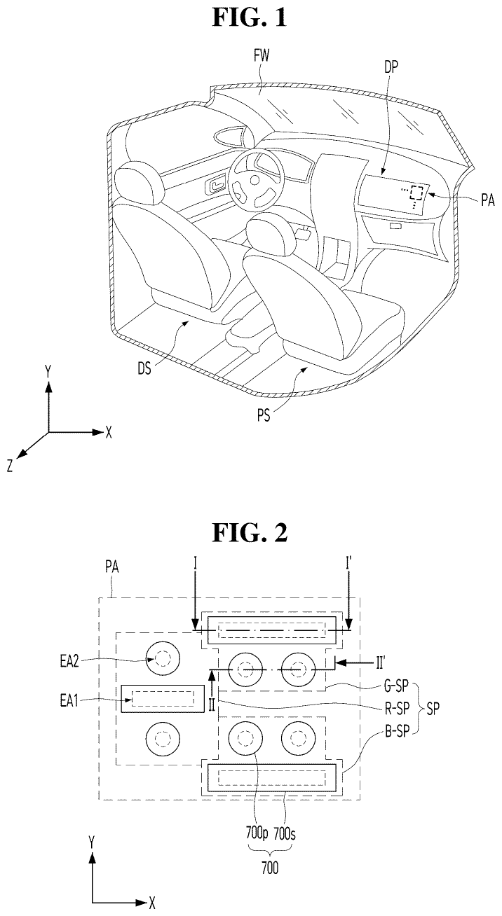

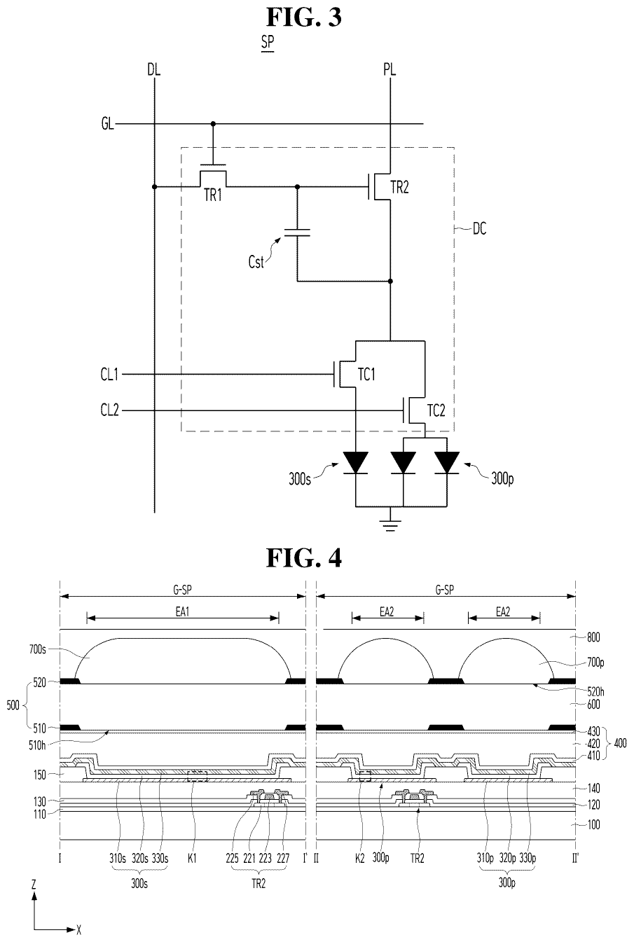

FIG. 1 is a view schematically showing a location where a display panel of a display apparatus according to an embodiment of the present disclosure is installed. FIG. 2 is an enlarged view of a pixel area in the display apparatus according to an embodiment of the present disclosure. FIG. 3 is a view showing a circuit of a sub-pixel in the display apparatus according to an embodiment of the present disclosure.

Referring to FIGS. 1 to 3, the display apparatus according to an embodiment of the present disclosure can include a display panel DP installed in a car. An image realized by the display panel DP can provide to a passenger sitting in a passenger seat PS. For example, the display panel DP can be installed in front of the passenger seat PS. The image realized by the display panel DP cannot be optionally recognized by a driver sitting in a driver seat DS. For example, the display panel DP can realize one of a first image shared in the passenger sitting in the passenger seat PS and the driver sitting in the driver seat DS and a second image which is not recognized by the driver sitting in the driver seat DS. Thus, in the display apparatus according to the embodiment of the present disclosure, accidents due to gaze dispersion of the driver while driving the car can be prevented or at least reduced.

A plurality of pixel areas PA can be disposed in the display panel DP. The pixel areas PA can be arranged in a matrix shape. For example, the pixel areas PA can be disposed side by side in a first direction X and a second direction Y perpendicular to the first direction X. Herein, the first direction X is a direction toward the passenger seat PS from the driver seat DS. A front wind-shield FW of the car can be disposed side by side with the display panel DP in the second direction Y. For example, a third direction Z perpendicular to the first direction X and the second direction Y can be a direction toward the passenger seat PS from the display panel DP.

Each of the pixel areas PA can display various colors. For example, each of the pixel areas PA can include sub-pixels SP. Each of the sub-pixels SP can display a specific color. For example, each of the pixel areas PA can be one of a red sub-pixel R-SP displaying a red color, a green sub-pixel G-SP displaying a green color, and a blue sub-pixel B-SP displaying a blue color. Each of the pixel areas PA can include the red sub-pixel R-SP, the green sub-pixel G-SP and the blue sub-pixel B-SP.

Various signals can be applied in each sub-pixel SP through signal wirings GL, DL, PL, CL1 and CL2. The signal wirings GL, DL, PL, CL1 and CL2 can include a gate line GL applying a gate signal, a data line DL applying a data signal, and a power voltage supply line PL supplying a power voltage. For example, each of the sub-pixel SP can emit light having luminance corresponding to the data signal using the power voltage according to the gate signal. A driving circuit DC electrically connected to the signal wirings GL, DL, PL, CL1 and CL2 and light-emitting devices 300s and 300p electrically connected to the driving circuit DC can be disposed in each sub-pixel SP.

The driving circuit DC can control the light-emitting devices 300s and 300p according to a signal applied through the signal wirings GL, DL, PL, CL1 and CL2. For example, the driving circuit DC can supply a driving current corresponding to the data signal according to the gate signal for one frame. The driving circuit DC can include a first thin film transistor TR1, a second thin film transistor TR2 and a storage capacitor Cst.

FIG. 4 is a view taken along I-I′ and II-II′ of FIG. 2 according to an embodiment of the present disclosure. FIG. 5 is an enlarged view of K1 region and K2 region in FIG. 4 according to an embodiment of the present disclosure.

Referring to FIGS. 2 to 5, the first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern, a first gate electrode, a first drain electrode and a first source electrode. For example, the first gate electrode can be electrically connected to the gate line GL, and the first drain electrode can be electrically connected to the date line DL.

The second thin film transistor TR2 can generate the driving current corresponding to the data signal using the power voltage. For example, the second thin film transistor TR2 can function as a driving thin film transistor. The second thin film transistor TR2 can have a same structure as the first thin film transistor TR1. For example, the second thin film transistor TR2 can include a second semiconductor pattern 221, a second gate electrode 223, a second drain electrode 225 and a second source electrode 227. The second gate electrode 223 can be electrically connected to the first source electrode, and the second drain electrode 225 can be electrically connected to the power voltage supply line PL.

The second semiconductor pattern 221 can include a semiconductor material. For example, the second semiconductor pattern 221 can include an oxide semiconductor, such as IGZO. The second semiconductor pattern 221 can include a drain region, a channel region and a source region. The channel region can be disposed between the drain region and the source region. A resistance of the drain region and a resistance of the source region can be smaller than a resistance of the channel region. The drain region and the source region can have an electrical conductivity greater than the channel region. For example, the drain region and the source region can include a conductive region of an oxide semiconductor. The channel region can be a region of an oxide semiconductor, which is not conductorized.

The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second gate electrode 223 can be disposed on a portion of the second semiconductor pattern 221. For example, the second gate electrode 223 can overlap the channel region of the second semiconductor pattern 221. The drain region and the source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the channel region of the second semiconductor pattern 221 can have an electrical conductivity corresponding to a voltage of a signal applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can be electrically connected to the drain region of the second semiconductor pattern 221. The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can be insulated from the second gate electrode 223. The second drain electrode 225 can include a different material from the second gate electrode 223. For example, the second drain electrode 225 can be disposed on a different layer from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can be electrically connected to the source region of the second semiconductor pattern 221. The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can be insulated from the second gate electrode 223. The second source electrode 227 can include a different material from the second gate electrode 223. For example, the second source electrode 227 can be disposed on a different layer from the second gate electrode 223.

The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be spaced apart from the second drain electrode 225.

The second source electrode 227 can include a same material as the first source electrode. The second source electrode 227 can be disposed on a same layer as the first source electrode. The second source electrode 227 can be formed by a same process as the first source electrode. For example, the second source electrode 227 can be formed simultaneously with the first source electrode.

The storage capacitor Cst can maintain a voltage of the signal applied to the second gate electrode 223 for one frame. For example, the storage capacitor Cst can be electrically connected to the second gate electrode 223 and the second source electrode 227. The storage capacitor Cst can have a stacked structure of capacitor electrodes. For example, the storage capacitor Cst can have a structure in which a first capacitor electrode electrically connected to the second gate electrode 233 and a second capacitor electrode electrically connected to the second source electrode 227 are stacked. The storage capacitor Cst can be formed using a process of forming the first thin film transistor TR1 and the second thin film transistor TR2. For example, the first capacitor electrode can be disposed on a same layer as the second gate electrode 223, and the second capacitor electrode can be disposed on a same layer as the second source electrode 227.

The driving circuit DC of each sub-pixel SP can be supported by a device substrate 100. The device substrate 100 can include an insulating material. For example, the device substrate 100 can include glass or plastic. At least one insulating layer 110, 120, 130, 140 and 150 for preventing unnecessary electrical connection can be disposed on the device substrate 100. For example, a buffer insulating layer 110, a gate insulating layer 120, an interlayer insulating layer 130, a device planarization layer 140 and a bank insulating layer 150 can be disposed on the device substrate 100.

The buffer insulating layer 110 can be disposed on the device substrate 100. The buffer insulating layer 110 can prevent or at least reduce pollution due to the device substrate 100 in a process of forming the driving circuit DC of each sub-pixel SP. For example, an upper surface of the device substrate 100 toward the driving circuit DC of each sub-pixel can be covered by the buffer insulating layer 110. The first thin film transistor TR1, the second thin film transistor TR2 and the storage capacitor Cst of each sub-pixel SP can be disposed on the buffer insulating layer 110. The buffer insulating layer 110 can include an insulating material. For example, the buffer insulating layer 110 can be an inorganic insulating layer made of an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

The gate insulating layer 120 can be disposed on the buffer insulating layer 110. The second gate electrode 223 of each sub-pixel SP can be insulated from the second semiconductor pattern 221 of the corresponding sub-pixel SP by the gate insulating layer 120. For example, the gate insulating layer 120 can cover the first semiconductor pattern and the second semiconductor pattern 221 of each sub-pixel SP. The first gate electrode and the second gate electrode 223 of each sub-pixel SP can be disposed on the gate insulating layer 120. The gate insulating layer 120 can include an insulating material. For example, the gate insulating layer 120 can be an inorganic insulating layer made of an inorganic insulating material, such as silicon oxide (SiOx) and silicon nitride (SiNx).

The interlayer insulating layer 130 can be disposed on the gate insulating layer 120. The second drain electrode 225 and the second source electrode 227 of each sub-pixel SP can be insulated from the second gate electrode 223 of the corresponding sub-pixel SP by the interlayer insulating layer 130. For example, the interlayer insulating layer 130 can cover the first gate electrode and the second gate electrode 223 of each sub-pixel SP. The first drain electrode, the first source electrode, the second drain electrode 225 and the second source electrode 227 of each sub-pixel SP can be disposed on the interlayer insulating layer 130. The interlayer insulating layer 130 can include an insulating material. For example, the interlayer insulating layer 130 can be an inorganic insulating layer made of an inorganic insulating material.

The device planarization layer 140 can be disposed on the interlayer insulating layer 130. A thickness difference due to the driving circuit DC of each sub-pixel SP can be removed by the device planarization layer 140. For example, the first drain electrode, the first source electrode, the second drain electrode 225 and the second source electrode 227 of each sub-pixel SP can be covered by the device planarization layer 140. The device planarization layer 140 can include an insulating material. The planarization layer 140 can include a material having a relative high fluidity. For example, the planarization layer 140 can be an organic insulating layer made of an organic insulating material. An upper surface of the device planarization layer 140 opposite to the device substrate 100 can be flat. For example, the upper surface of the device planarization layer 140 can be parallel to the upper surface of the device substrate 100.

The bank insulating layer 150 can be disposed on the device planarization layer 140. The bank insulating layer 150 can include an insulating material. For example, the bank insulating layer 150 can be an organic insulating layer made of an organic insulating material. The bank insulating layer 150 can include a different material from the device planarization layer 140. The bank insulating layer 150 can define a first emission area EA1 and a second emission area EA2 in each sub-pixel SP. For example, a portion of the upper surface of the device planarization layer 140 overlapping with the first emission area EA of each sub-pixel SP and a portion of the upper surface of the device planarization layer 140 overlapping with the second emission area EA2 of each sub-pixel SP can be exposed by the bank insulating layer 150.

The number of the second emission area EA2 defined by the bank insulating layer 150 in each sub-pixel SP can be different from the number of the first emission area EA1 defined by the bank insulating layer 150 in the corresponding sub-pixel SP. For example, a single first emission area EA1 and two second emission areas EA2 can be defined in each sub-pixel SP. The first emission area EA1 and the second emission area EA2 of each sub-pixel SP can be arranged in various ways. The first emission area EA1 and the second emission area EA2 of each sub-pixel SP can be arranged differently from the first emission area EA1 and the second emission area EA2 of the adjacent sub-pixel SP. For example, the first emission area EA1 of each red sub-pixel R-SP can be disposed between two second emission areas EA2 defined in the corresponding red sub-pixel R-SP in a plan view of the display device, and two second emission areas EA2 defined in each green sub-pixel G-SP can be disposed side by side in the first direction X within the corresponding green sub-pixel G-SP in the plan view. The first emission area EA1 and the second emission area EA2 of each blue sub-pixel B-SP can be symmetrical to the first emission area EA1 and the second emission area EA2 of each green sub-pixel G-SP to respect with the first direction X in the plan view.

The second emission area EA2 can have a planar shape that is different from a planar shape of the first emission area EA1. A length of the first emission area EA1 in the first direction X can be longer than a length of the second emission area EA2 in the first direction X. For example, the first emission area SEA can have a planar shape of a bar extending in the first direction X in the plan view, and a planar shape of the second emission area EA2 can have a circular shape in the plan view.

The light-emitting devices 300s and 300p of each sub-pixel SP can be disposed on the device planarization layer 140. The light-emitting devices 300s and 300p of each sub-pixel SP can be corresponding to the first emission area EA1 and the second emission area EA2 defined in the corresponding sub-pixel SP. For example, the light-emitting devices 300s and 300p of each sub-pixel SP can include a first light-emitting device 300s overlapping with the first emission area EA1 of the corresponding sub-pixel SP and a second light-emitting device 300p overlapping with the second emission area EA2 of the corresponding sub-pixel SP.

The first light-emitting device 300s can be disposed on a portion of the upper surface of the device planarization layer 140 overlapping with the first emission area EA1 exposed by the bank insulating layer 150. The first light-emitting device 300s can emit a first light. For example, the first light-emitting device 300s can include a first lower electrode 310s, a first light-emitting unit 320s and a first upper electrode 330s, which are sequentially stacked on the upper surface of the device planarization layer 140.

The first lower electrode 310s can be disposed close to the device planarization layer 140. For example, a lower surface of the first lower electrode 310s toward the device substrate 100 can be in direct contact with the upper surface of the device planarization layer 140. The first lower electrode 310s can include a material having a relative high reflectance. For example, the first lower electrode 310s can include a metal, such as aluminum (Al) and silver (Ag). The first lower electrode 310s can have a multi-layer structure. For example, the first lower electrode 310s can have a structure in which a reflective electrode made of a metal is disposed between transparent electrodes made of a transparent conductive material, such as ITO and IZO.

The first light-emitting unit 320s can generate a first light having luminance corresponding to a voltage difference between the first lower electrode 310s and the first upper electrode 330s. For example, the first light-emitting unit 320s can include a first emission material layer 320sem. The first emission material layer 320sem can generate light using holes and electrons. For example, the first emission material layer 320sem can include a first dopant doped in a first host.

The first light-emitting unit 320s can further include at least one first functional layer. The first function layer can be disposed between the first lower electrode 310s and the first emission material layer 320sem and/or the first emission material layer 320sem and the first upper electrode 330s. Holes or electrons can be smoothly supplied to the first emission material layer 320sem by the first function layer. For example, the first function layer can be a hole injection layer (HIL), a hole transport layer (HTL), an electron transport layer (ETL) or an electron injection layer (EIL). In the display apparatus according to the embodiment of the present disclosure, a first hole injection layer 320shi and a first hole transport layer 320sht can be stacked between the first lower electrode 310s and the first emission material layer 320sem, and a first electron transport layer 320set and a first electron injection layer 320sei can be stacked between the first emission material layer 320sem and the first upper electrode 330s. That is, in the display apparatus according to the embodiment of the present disclosure, the first light-emitting unit 320s can include the first hole injection layer 320shi, the first hole transport layer 320sht, the first emission material layer 320sem, the first electron transport layer 320set and the first electron injection layer 320sei, which are sequentially stacked on an upper surface of the first lower electrode 310s toward the first upper electrode 330s.

The first upper electrode 330s can include a conductive material. The first upper electrode 330s can include a different material from the first lower electrode 310s. A transmittance of the first upper electrode 330s can be higher than a transmittance of the first lower electrode 310s. For example, the first upper electrode 330s can be a transparent electrode made of a transparent conductive material, such as ITO and IZO, or a translucent electrode in which a metal, such as silver (Ag) and magnesium (Mg) is thinly formed. Thus, in the display apparatus according to the embodiment of the present disclosure, the first light generated by the first light-emitting unit 320s can be emitted outside through the first upper electrode 330s. A work-function of the first upper electrode 330s can be different from a work-function of the first lower electrode 310s. For example, the first upper electrode 330s can have a smaller work-function than the first lower electrode 310s. Therefore, in the display apparatus according to the embodiment of the present disclosure, the first lower electrode 310s can function as an anode, and the first upper electrode 330s can function as a cathode.

The second light-emitting device 300p can be disposed on a portion of the upper surface of the device planarization layer 140 overlapping with the second emission area EA2 exposed by the bank insulating layer 150. For example, the second light-emitting device 300p can include a second lower electrode 310p, a second light-emitting unit 320p and a second upper electrode 330p, which are sequentially stacked on the upper surface of the device planarization layer 140.

The second lower electrode 310p can be disposed close to the device planarization layer 140. For example, a lower surface of the second lower electrode 310p toward the device substrate 100 can be in direct contact with the upper surface of the device planarization layer 140. The second lower electrode 310p can include a material having a relative high reflectance. For example, the second lower electrode 310p can include a metal, such as aluminum (Al) and silver (Ag). The second lower electrode 310p can have a multi-layer structure. For example, the second lower electrode 310p can have a structure in which a reflective electrode made of a metal is disposed between transparent electrodes made of a transparent conductive material, such as ITO and IZO.

The second lower electrode 310p can be disposed on a same layer as the first lower electrode 310s. The second lower electrode 310p can be formed by a same process as the first lower electrode 310s. For example, the second lower electrode 310p can be formed simultaneously with the first lower electrode 310s. A stacked structure of the second lower electrode 310p can be a same as a stacked structure of the first lower electrode 310s. A thickness of the second lower electrode 310p can be a same as a thickness of the first lower electrode 310s.

The second lower electrode 310p can be spaced apart from the first lower electrode 310s. The second lower electrode 310p can be insulated from the first lower electrode 310s. For example, an edge of the first lower electrode 310s and an edge of the second lower electrode 310p can be covered by the bank insulating layer 150. Thus, in the display apparatus according to an embodiment of the present disclosure, the second light-emitting device 300p can be independently controlled from the first light-emitting device 300s.

The second light-emitting unit 320p can generate a second light having luminance corresponding to a voltage difference between the second lower electrode 310p and the second upper electrode 330p. For example, the second light-emitting unit 320p can include a second emission material layer 320pem. The second emission material layer 320pem can generate light using holes and electrons. For example, the second emission material layer 320pem can include a second dopant doped in a second host.

The second light-emitting unit 320p can further include at least one second functional layer. The second function layer can be disposed between the second lower electrode 310p and the second emission material layer 320pem and/or the second emission material layer 320pem and the second upper electrode 330p. Holes or electrons can be smoothly supplied to the second emission material layer 320pem by the second function layer. For example, in the display apparatus according to the embodiment of the present disclosure, a second hole injection layer 320phi and a second hole transport layer 320pht can be stacked between the second lower electrode 310p and the second emission material layer 320pem, and a second electron transport layer 320pet and a second electron injection layer 320pei can be stacked between the second emission material layer 320pem and the second upper electrode 330p. In the display apparatus according to the embodiment of the present disclosure, the second light-emitting unit 320p can include the second hole injection layer 320phi, the second hole transport layer 320pht, the second emission material layer 320pem, the second electron transport layer 320pet and the second electron injection layer 320pei, which are sequentially stacked on an upper surface of the second lower electrode 310p toward the second upper electrode 330p.

The second hole injection layer 320phi can be formed of a same material as the first hole injection layer 320shi. A composition ratio of the second hole injection layer 320phi can be a same as a composition ratio of the first hole injection layer 320shi. For example, the second hole injection layer 320phi can be formed simultaneously with the first hole injection layer 320shi. A thickness of the second hole injection layer 320phi can be a same as a thickness of the first hole injection layer 320shi.

The second hole transport layer 320pht can be formed of a same material as the first hole transport layer 320sht. A composition ratio of the second hole transport layer 320pht can be a same as a composition ratio of the first hole transport layer 320sht. For example, the second hole transport layer 320pht can be formed simultaneously with the first hole transport layer 320sht. A thickness of the second hole transport layer 320pht can be a same as a thickness of the first hole transport layer 320sht.

The second electron transport layer 320pet can be formed of a same material as the first electron transport layer 320set. A composition ratio of the second electron transport layer 320p3t can be a same as a composition ratio of the first electron transport layer 320set. For example, the second electron transport layer 320pet can be formed simultaneously with the first electron transport layer 320set. A thickness of the second electron transport layer 320pet can be a same as a thickness of the first electron transport layer 320set.

The second electron injection layer 320pei can be formed of a same material as the first electron injection layer 320sei. A composition ratio of the second electron injection layer 320pei can be a same as a composition ratio of the first electron injection layer 320sei. For example, the second electron injection layer 320pei can be formed simultaneously with the first electron injection layer 320sei. A thickness of the second electron injection layer 320pei can be a same as a thickness of the first electron injection layer 320sei.

The second light-emitting unit 320p can be spaced apart from the first light-emitting unit 320s. For example, an upper surface of the bank insulating layer 150 opposite to the device substrate 100 can be partially exposed by the first light-emitting unit 320s and the second light-emitting unit 320p. Each of the first light-emitting unit 320s and the second light-emitting unit 320p can include an end portion disposed on the upper surface of the bank insulating layer 150.

The second upper electrode 330p can include a conductive material. The second upper electrode 330p can include a different material from the second lower electrode 310p. A transmittance of the second upper electrode 330p can be higher than a transmittance of the second lower electrode 310p. For example, the second upper electrode 330p can be a transparent electrode made of a transparent conductive material, such as ITO and IZO, or a translucent electrode in which a metal, such as silver (Ag) and magnesium(Mg) is thinly formed. Thus, in the display apparatus according to the embodiment of the present disclosure, the second light generated by the second light-emitting unit 320p can be emitted outside through the second upper electrode 330p. A work-function of the second upper electrode 330p can be different from a work-function of the second lower electrode 310p. For example, the second upper electrode 330p can have a smaller work-function than the second lower electrode 310p. Therefore, in the display apparatus according to the embodiment of the present disclosure, the second lower electrode 310p can function as an anode, and the second upper electrode 330p can function as a cathode.

A signal applied to the second upper electrode 330p of each sub-pixel SP can be the same as a signal applied to the first upper electrode 330s of the corresponding sub-pixel SP. For example, the second upper electrode 330p of each sub-pixel SP can be electrically connected to the first upper electrode 330s of the corresponding sub-pixel SP. Thus, in the display apparatus according to the embodiment of the present disclosure, the luminance of the first light generated by the first light-emitting unit 320s of each sub-pixel SP can be symmetrical to the driving current applied to the first lower electrode 310s of the corresponding sub-pixel SP, and the luminance of the second light generated by the second light-emitting unit 320p of each sub-pixel SP can be symmetrical to the driving current applied to the second lower electrode 310p of the corresponding sub-pixel SP.

The second upper electrode 330p of each sub-pixel SP can include a same material as a first upper electrode 330s of the corresponding sub-pixel SP. The second upper electrode 330p of each sub-pixel SP can have a same work-function as the first upper electrode 330s of the corresponding sub-pixel SP. The second upper electrode 330p of each sub-pixel SP can be formed by a same process as the first upper electrode 330s of the corresponding sub-pixel SP. For example, the second upper electrode 330p of each sub-pixel SP can be formed simultaneously with the first upper electrode 330s of the corresponding sub-pixel SP. The second upper electrode 330p of each sub-pixel SP can be in direct contact with the first upper electrode 330s of the corresponding sub-pixel SP. Thus, in the display apparatus according to the embodiment of the present disclosure, a process of forming the first upper electrode 330s and the second upper electrode 330p of each sub-pixel SP can be simplified. Therefore, in the display apparatus according to the embodiment of the present disclosure, the process efficiency can be improved.

The second emission area EA1 of each sub-pixel SP can be display a same color as the first emission area EA1 of the corresponding sub-pixel SP. For example, the first light-emitting device 300s and the second light-emitting device 300p of each red sub-pixel R-SP can emit red light, the first light-emitting device 300s and the second light-emitting device 300p of each green sub-pixel G-SP can emit green light, and the first light-emitting device 300s and the second light-emitting device 300p of each blue sub-pixel B-SP can emit blue light.

A color of each sub-pixel SP can be realized by the first light-emitting device 300s of the corresponding sub-pixel SP or the second light-emitting device 300p of the corresponding sub-pixel SP. For example, the driving current generated by the driving circuit DC of each sub-pixel SP can be supplied to the first lower electrode 310s of the corresponding sub-pixel SP or the second lower electrodes 310p of the corresponding sub-pixel SP. In the display apparatus according to the embodiment of the present disclosure, the driving circuit DC of each sub-pixel SP can include a first control thin film transistor TC1 disposed between the second source electrode 227 and the first lower electrode 310s of the corresponding sub-pixel SP and a second control thin film transistor TC2 disposed between the second source electrode 227 and the second lower electrode 310p of the corresponding sub-pixel SP, and the signal wirings GL, DL, PL, CL1 and CL2 can include a first control line CL1 applying a first control signal for turning on/off the first control thin film transistor TC1 and a second control line CL2 applying a second control signal for turning on/off the second control thin film transistor TC2, as shown in FIG. 3. Thus, in the display apparatus according to the embodiment of the present disclosure, the first image by the first light-emitting device 300s of each sub-pixel SP or the second image by the second light-emitting device 300p of each sub-pixel SP can be optionally provided.

As shown in FIG. 4, an encapsulation structure 400 can be disposed on the light-emitting devices 300s and 300p of each sub-pixel SP. The encapsulation structure 400 can prevent or at least reduce the damage of the light-emitting devices 300s and 300p in each sub-pixel SP1 due to external impact and moisture. The encapsulation structure 400 can have a multi-layer structure. For example, the encapsulation structure 400 can include a first encapsulating layer 410, a second encapsulating layer 420, and a third encapsulating layer 430, which are sequentially stacked on the first upper electrode 330s and the second upper electrode 330p of each sub-pixel SP. The first encapsulating layer 410, the second encapsulating layer 420 and the third encapsulating layer 430 can include an insulating material.

The second encapsulating layer 420 can include a different material from the first encapsulating layer 410 and the third encapsulating layer 430. For example, the first encapsulating layer 410 and the third encapsulating layer 430 can be an inorganic insulating layer made of an inorganic insulating material, and the second encapsulating layer 420 can be an organic insulating layer made of an organic insulating material. The third encapsulating layer 430 can include a same material as the first encapsulating layer 410. Thus, in the display apparatus according to the embodiment of the present disclosure, the damage of the light-emitting devices 300s and 300p in each sub-pixel SP1 due to the external impact and moisture can be effectively prevented. A thickness difference due to the light-emitting devices 300s and 300p of each sub-pixel SP can be removed by the second encapsulating layer 420. For example, an upper surface of the encapsulation structure 400 opposite to the device substrate 100 can be flat.

A barrier structure 500 can be disposed on the encapsulation structure 400. The barrier structure 500 can limit a travelling direction of the light emitted from each light-emitting device 300s and 300p. The barrier structure 500 can have a multi-layer structure. For example, the barrier structure 500 can have a stacked structure of a first barrier pattern 510 and a second barrier pattern 520.

The first barrier pattern 510 can be disposed closer to the encapsulation structure 400 than the second barrier pattern 520. For example, a lower surface of the first barrier pattern 510 toward the device substrate 100 can be in direct contact with the upper surface of the encapsulation structure 400. The first barrier pattern 510 can include a material capable of blocking light. For example, the first barrier pattern 510 can include a black dye, such as carbon black. The first barrier pattern 510 can be disposed outside the first emission area EA1 and the second emission area EA2 defined in each sub-pixel SP. For example, the first barrier pattern 510 can include first openings 510h overlapping with the first emission area EA1 and the second emission area EA2 of each sub-pixel SP. A region disposed outside the emission areas EA1 and EA2 defined in each sub-pixel SP can define as a non-emission area, and the first barrier pattern 510 can be disposed within the non-emission area. For example, the first barrier pattern 510 can overlap the bank insulating layer 150.

The second barrier pattern 520 can be disposed on the first barrier pattern 510. The second barrier pattern 520 can be spaced apart from the first barrier pattern 510. For example, an optical insulating layer 600 covering the first barrier pattern 510 can be disposed on the encapsulation structure 400, and the second barrier pattern 520 can be disposed on an upper surface of the optical insulating layer 600 opposite to the device substrate 100. The optical insulating layer 600 can include an insulating material. The optical insulating layer 600 can include a transparent material. For example, the optical insulating layer 600 can include an organic insulating material. The upper surface of the optical insulating layer 600 can be flat. The optical insulating layer 600 can overlap the first emission area EA1 and the second emission area EA2 of each sub-pixel SP. For example, the first openings 510h of the first barrier pattern 510 can be filled by the optical insulating layer 600. Thus, in the display apparatus according to the embodiment of the present disclosure, an optical distance of the first light emitted from the first light-emitting device 300s of each sub-pixel SP and an optical distance of the second light emitted from the second light-emitting device 300p of each sub-pixel SP can be sufficiently secured by the optical insulating layer 600.

A lower surface of the second barrier pattern 520 toward the device substrate 100 can be in direct contact with the upper surface of the optical insulating layer 600. The second barrier pattern 520 can include a material capable of blocking light. For example, the second barrier pattern 520 can include a black dye, such as carbon black. The second barrier pattern 520 can include a same material as the first barrier pattern 510. The second barrier pattern 520 can be formed by a same process as the first barrier pattern 510. Thus, in the display apparatus according to the embodiment of the present disclosure, a process of forming the barrier structure 500 can be simplified.

The second barrier pattern 520 can be disposed outside the first emission area EA1 and the second emission area EA2 defined in each sub-pixel SP. For example, the second barrier pattern 520 can be disposed within the non-emission area. The second barrier pattern 520 can include second openings 520h overlapping with the first emission area EA1 and the second emission area EA2 of each sub-pixel SP. A portion of the upper surface of the optical insulating layer 600 overlapping with the first emission area EA1 of each sub-pixel SP and a portion of the upper surface of the optical insulating layer 600 overlapping with the second emission area EA2 of each sub-pixel SP can be exposed by the second openings 520h of the second barrier pattern 520. The second barrier pattern 520 can overlap the first barrier pattern 510. For example, the second barrier pattern 520 can have a planar shape same as the first barrier pattern 510. Thus, in the display apparatus according to the embodiment of the present disclosure, the unintended color mixing and the light leakage can be prevented or at least reduced.

Pixel lenses 700 can be disposed on a portion of the optical insulating layer 600 that is exposed by the second barrier pattern 520. For example, the pixel lenses 700 can include a first pixel lens 700s overlapping with the first emission area EA1 of each sub-pixel SP and second pixel lenses 700p overlapping with the second emission area EA2 of each sub-pixel SP.

The first light emitted from the first light-emitting device 300s of each sub-pixel SP can be focused by one of the first pixel lenses 700s. For example, the first pixel lenses 700s can function as a convex lens. A surface of each first pixel lens 700s opposite to the optical insulating layer 600 can have a convex shape. A lower surface of each first pixel lens 700s toward the optical insulating layer 600 can be in direct contact with the optical insulating layer 600. For example, some of the second openings 520h of the second barrier pattern 520 exposing a portion of the upper surface of the optical insulating layer 600 overlapping with the first emission area EA1 of each sub-pixel SP can be filled by the first pixel lenses 700s. A size of the first pixel lens 700s on each sub-pixel SP can be larger than a size of the first emission area EA1 defined in the corresponding sub-pixel SP. For example, an edge of each first pixel lens 700s can overlap the second barrier pattern 520. Thus, in the display apparatus according to the embodiment of the present disclosure, the light extraction efficiency of the first light generated by the first light-emitting device 300s of each sub-pixel SP can be improved.

As shown in FIGS. 1, 2 and 4, each of the first pixel lenses 700s can have a planar shape corresponding to a planar shape of the first emission area EA1 of one of the sub-pixels SP. For example, a planar of each first pixel lens 700s can have a shape of a bar extending in the first direction X and the planar shape of the first emission area EA1 also has a bar shape extending in the first direction X. Thus, in the display apparatus according to the embodiment of the present disclosure, the first light emitted from the first emission area EA1 of each sub-pixel SP1 can be spread widely in the first direction X. That is, in the display apparatus according to the embodiment of the present disclosure, the first image realized by the first light-emitting device 300s of each sub-pixel SP can have a wide viewing angle in the first direction X during a first mode (e.g., a wide viewing angle mode). The first mode of the display apparatus may be activated when the first control signal on the first control line CL1 turns on the first control thin film transistor TC1 and the second control signal on the second control line CL2 turns off the second control thin film transistor TC2. During the first mode, the display apparatus displays an image having the wide viewing angle (e.g., a first viewing angle). Therefore, in the display apparatus according to the embodiment of the present disclosure, the passenger sitting in the passenger seat PS and the driver sitting in the driver seat DS can share the first image realized by the first light-emitting device 300s of each sub-pixel SP. For example, in the display apparatus according to the embodiment of the present disclosure, the first image can contain information necessary for the driving of the car.

The second light emitted from the second light-emitting device 300p of each sub-pixel SP can be focused by one of the second pixel lenses 700p. For example, the second pixel lenses 700p can function as a convex lens. A surface of each second pixel lens 700p opposite to the optical insulating layer 600 can have a convex shape. A lower surface of each second pixel lens 700p toward the optical insulating layer 600 can be in direct contact with the optical insulating layer 600. For example, some of the second openings 520h of the second barrier pattern 520 exposing a portion of the upper surface of the optical insulating layer 600 overlapping with the second emission area EA2 of each sub-pixel SP can be filled by the second pixel lenses 700p. A size of the second pixel lens 700p on each sub-pixel SP can be larger than a size of the second emission area EA2 defined in the corresponding sub-pixel SP. Thus, in the display apparatus according to the embodiment of the present disclosure, the light extraction efficiency of the second light generated by the second light-emitting device 300p of each sub-pixel SP can be improved.

The second pixel lenses 700p can include a same material as the first pixel lenses 700s. The second pixel lenses 700p can be disposed on a same layer as the first pixel lenses 700s. The second pixel lenses 700p can be formed by a same process as the first pixel lenses 700s. For example, the second pixel lenses 700p can be formed simultaneously with the first pixel lenses 700s. Thus, in the display apparatus according to the embodiment of the present disclosure, a process of forming the pixel lenses 700 can be simplified.

Each of the second pixel lenses 700p can have a planar shape corresponding to a planar shape of the second emission area EA2 of one of the sub-pixels SP. For example, a planar shape of each second pixel lens 700p can have a circular shape and a planar shape of the second emission area EA2 of one of the sub-pixels SP is also a circular shape. Thus, in the display apparatus according to the embodiment of the present disclosure, the second image realized by the second light-emitting device 300p of each sub-pixel SP can have a narrow viewing angle in the first direction X during a second mode (e.g., a narrow viewing angle mode). The second mode may be activated when the second control signal on the second control line CL2 turns on the second control thin film transistor TC2 and the first control signal on the first control line CL1 turns off the first control thin film transistor TC1. During the second mode, the display apparatus displays an image having the narrow viewing angle (e.g., a second viewing angle). That is, in the display apparatus according to the embodiment of the present disclosure, the second image realized by the second light-emitting device 300p of each sub-pixel SP cannot be recognized by the driver sitting in the driver seat DS. For example, in the display apparatus according to the embodiment of the present disclosure, the second image can contain information unrelated to the driving of the car. Therefore, in the display apparatus according to the embodiment of the present disclosure, gaze dispersion of the driver due to the second image containing information unrelated to the driving of the car can be prevented.

The second light realizing the second image can have different characteristics from the first light realizing the first image. The second dopant of the second emission material layer 320pem can include a different material from the first dopant of the first emission material layer 320sem in at least one of the sub-pixels SP of each pixel area PA. For example, in the display apparatus according to the embodiment of the present disclosure, the first emission material layer 320sem of each green sub-pixel G-SP can include a fluorescent dopant having a strong double bond structure based on a covalent bond, and the second emission material layer 320pem of each green sub-pixel G-SP can include a phosphorescent dopant in which a central metal, such as iridium (Ir), platinum (Pt), osmium (Os), gold (Au), titanium (Ti), zirconium (Zr), hafnium (Hf), europium (Eu), terbium (Tb) and thulium (Tm) is coordinated with an aromatic compound.

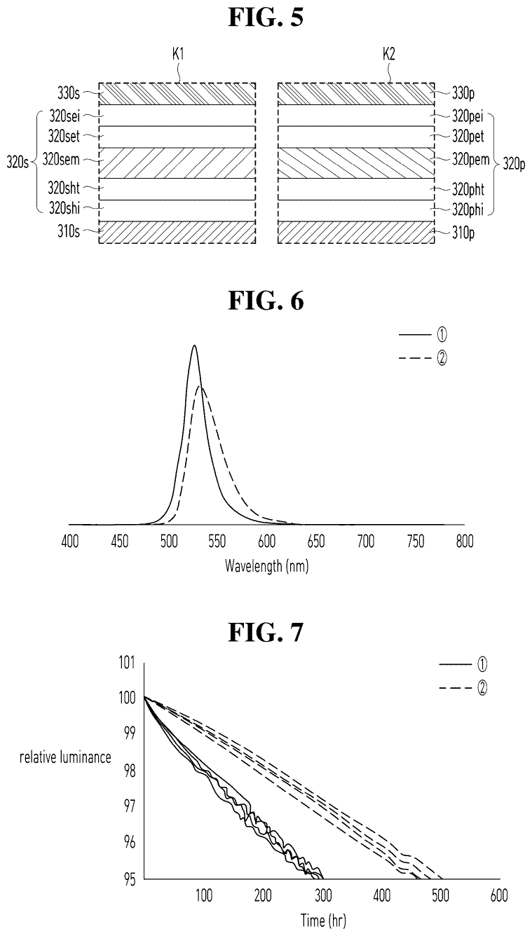

FIG. 6 is a graph showing simulation results for an EL spectrum of a first green light \textcircled{1} emitted from the light-emitting device including a green fluorescent dopant and an EL spectrum of a second green light \textcircled{2} emitted from the light-emitting device including a green phosphorescent dopant. FIG. 7 is a graph showing simulation results for a relative luminance of the first green light \textcircled{1} and the second green light \textcircled{2} according to usage time. Herein, the EL spectrum can be calculated by multiplying the PL spectrum, which is a unique characteristic of the dopant included in the emission material layer, by the out-coupling curve, which is an optical characteristic by the stacked structure of the light-emitting unit including the corresponding emission material layer.

Referring to FIGS. 6 and 7, the EL spectrum of the second green light \textcircled{2} can have a peak wavelength λmax different from the EL spectrum of the first green light \textcircled{1}, and the EP spectrum of the first green light \textcircled{1} can have a full width at half maximum (FWHM) that is smaller than the EL spectrum of the second green light \textcircled{2}. And, the first green light \textcircled{1} can have the maximum luminance greater than the second green light \textcircled{2}, and the relative luminance of the first green light \textcircled{1} according to usage time can decrease faster than the relative luminance of the second green light \textcircled{2} according to usage time. Thus, in the display apparatus according to the embodiment of the present disclosure, the first light-emitting device 300s of each green sub-pixel G-SP including a green fluorescent dopant can emit light having greater luminance than the second light-emitting device 300p of each green sub-pixel G-SP including a green phosphorescent dopant, and the second light-emitting device 300p of each green sub-pixel G-SP can have a longer lifespan than the first light-emitting device 300s of each green sub-pixel G-SP. Generally, the second image can be provided to the passenger sitting in the passenger seat PS while driving the car, and the second light-emitting device 300p of each sub-pixel SP is driven for a longer time than the first light-emitting device 300s of each sub-pixel SP. That is, in the display apparatus according to the embodiment of the present disclosure, the clarity of the first image having a wide viewing angle can be improved by the light having a great luminance, and the deterioration in the quality of the second image realized for a longer time than the first image according to time implemented can be reduced. Therefore, in the display apparatus according to the embodiment of the present disclosure, the variation in the quality between the first image and the second image due to the difference in realization time can be minimized, without the deterioration in the quality of the first image.

As shown in FIG. 4, a lens passivation layer 800 can be disposed on the first pixel lenses 700s and the second pixel lenses 700p. The lens passivation layer 800 can prevent or at least reduce the damage of the first pixel lenses 700s and the damage of the second pixel lenses 700p due to the external impact. For example, the first pixel lenses 700s and the second pixel lenses 700p can be completely covered by the lens passivation layer 800. The lens passivation layer 800 can include an insulating material. The lens passivation layer 800 can include a transparent material. For example, the lens passivation layer 800 can include an organic insulating material. An upper surface of the lens passivation layer 800 opposite to the device substrate 100 can be flat.

A refractive index of the lens passivation layer 800 can be smaller than a refractive index of each first pixel lens 700s and a refractive index of each second pixel lens 700p. Thus, in the display apparatus according to the embodiment of the present disclosure, the first light passing through each first pixel lens 700s cannot be reflected toward the device substrate 100 at a boundary between the corresponding first pixel lens 700s and the lens passivation layer 800, and the second light passing through each second pixel lens 700p cannot be reflected toward the device substrate 100 at a boundary between the corresponding second pixel lens 700p and the lens passivation layer 800. Therefore, in the display apparatus according to the embodiment of the present disclosure, the light extraction efficiency can be improved.

Accordingly, the display apparatus according to the embodiment of the present disclosure can comprising the first light-emitting device 300s disposed between the first emission area EA1 and the first pixel lens 700s of each sub-pixel SP and the second light-emitting device 300p disposed between the second emission area EA2 and the second pixel lens 700p of each sub-pixel SP, wherein the first light emitted from the first light-emitting device 300s of each sub-pixel SP can have a relative large efficiency, and the second light emitted from the second light-emitting device 300p of each sub-pixel SP can have a relative long lifespan. Thus, in the display apparatus according to the embodiment of the present disclosure, the quality of the first image shared with the driver sitting in the driver seat DS and the passenger sitting in the passenger seat PS can be improved, and the difference in the quality between the first image and the second image due to the relatively long realization time of the second image that is not recognized by the driver sitting in the driver seat DS can be minimized. Therefore, in the display apparatus according to the embodiment of the present disclosure, the overall lifespan can be increased. And, in the display apparatus according to the embodiment of the present disclosure, the low power operation can be possible, and the power consumption can be reduced.

The display apparatus according to the embodiment of the present disclosure is described that the driving circuit DC of each sub-pixel SP includes the first thin film transistor TR1, the second thin film transistor TR2 and the storage capacitor Cst. However, in the display apparatus according to another embodiment of the present disclosure, the driving circuit DC of each sub-pixel SP can include a driving thin film transistor and at least one switching thin film transistor. For example, in the display apparatus according to another embodiment of the present disclosure, the driving circuit DC of each sub-pixel SP can further include a third thin film transistor to initialize the storage capacitor Cst of the corresponding sub-pixel SP according to the gate signal. The third thin film transistor of each sub-pixel SP can include a third semiconductor pattern, a third gate electrode, a third drain electrode and a third source electrode. The third semiconductor pattern of each sub-pixel SP can include a semiconductor pattern. The third gate electrode of each sub-pixel SP can be electrically connected to the gate line GL. The third drain electrode of each sub-pixel SP can be electrically connected to an initial line applying an initial signal. The third source electrode of each sub-pixel SP can be electrically connected to the storage capacitor Cst of the corresponding sub-pixel SP. Thus, in the display apparatus according to another embodiment of the present disclosure, the degree of freedom in the configuration of the driving circuit DC in each sub-pixel SP can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that a single first emission areas EA1 and two second emission area EA2 are defined in each sub-pixel SP. However, in the display apparatus according to another embodiment of the present disclosure, the second emission area EA2 of each sub-pixel SP1 can have the number according to a color displayed by the corresponding sub-pixel SP. For example, in the display apparatus according to another embodiment of the present disclosure, two second emission areas EA2 can be defined in each red sub-pixel R-SP and three second emission areas EA2 can be defined in each blue sub-pixel B-SP and each green sub-pixel G-SP. Thus, in the display apparatus according to another embodiment of the present disclosure, the degree of freedom in the configuration of each sub-pixel SP can be improved.

The display apparatus according to the embodiment of the present disclosure is described that the second light-emitting device 300p of each sub-pixel SP has a same thickness as the first light-emitting device 300s of the corresponding sub-pixel SP. However, in the display apparatus according to another embodiment of the present disclosure, the first light-emitting device 300s and the second light-emitting device 300p of each sub-pixel SP can have different thicknesses. For example, in the display apparatus according to another embodiment of the present disclosure, the first light-emitting device 300s of each sub-pixel SP can be thicker than the second light-emitting device 300p of the corresponding sub-pixel SP. Thus, in the display apparatus according to another embodiment of the present disclosure, the variation in color sense due to the difference in the peak wavelength λmax and the full width at half maximum (FWHM) between the first light emitted from the first light-emitting device 300s of each sub-pixel SP and the second light emitted from the second light-emitting device 300p of each sub-pixel SP can be minimized. That is, in the display apparatus according to another embodiment of the present disclosure, the second light for the realization of the second image can have a color reproduction rate same as the first light for the realization of the first image. Therefore, in the display apparatus according to another embodiment of the present disclosure, the difference in the quality between the first image and the second image, which are recognized by a user can be significantly reduced.

The display apparatus according to the embodiment of the present disclosure is described that the first emission material layer 320sem of each sub-pixel SP includes a fluorescent dopant, and the second emission material layer 320pem of each sub-pixel SP includes a phosphorescent dopant. However, in the display apparatus according to another embodiment of the present disclosure, the first emission material layer 320sem and the second emission material layer 320pem of each sub-pixel SP can include a same type of dopant. For example, in the display apparatus according to another embodiment of the present disclosure, the first emission material layer 320sem of each blue sub-pixel B-SP can include a boron-based dopant, and the second emission material layer 320pem of each blue sub-pixel B-SP can include a pyrene-based dopant. That is, in the display apparatus according to another embodiment of the present disclosure, the second emission material layer 320pem of each sub-pixel SP can have different characteristics from the first emission material layer 320sem of the corresponding sub-pixel SP in various ways. Thus, in the display apparatus according to another embodiment of the present disclosure, the variation in the quality between the first image and the second image due to the realization time can be minimized.

In the display apparatus according to the embodiment of the present disclosure, the second emission material layer 320pem of each sub-pixel SP can include a host made of a same material as the first emission material layer 320sem of the corresponding sub-pixel SP. However, in the display apparatus according to another embodiment of the present disclosure, the second host of each sub-pixel SP can be formed of a different material from the first host of the corresponding sub-pixel SP. For example, in the display apparatus according to another embodiment of the present disclosure, the second emission material layer 320p of each sub-pixel SP can include a host in which the deuterium is substituted. Thus, in the display apparatus according to another embodiment of the present disclosure, the lifespan of the second light-emitting device 320p in each sub-pixel SP can be greatly improved.

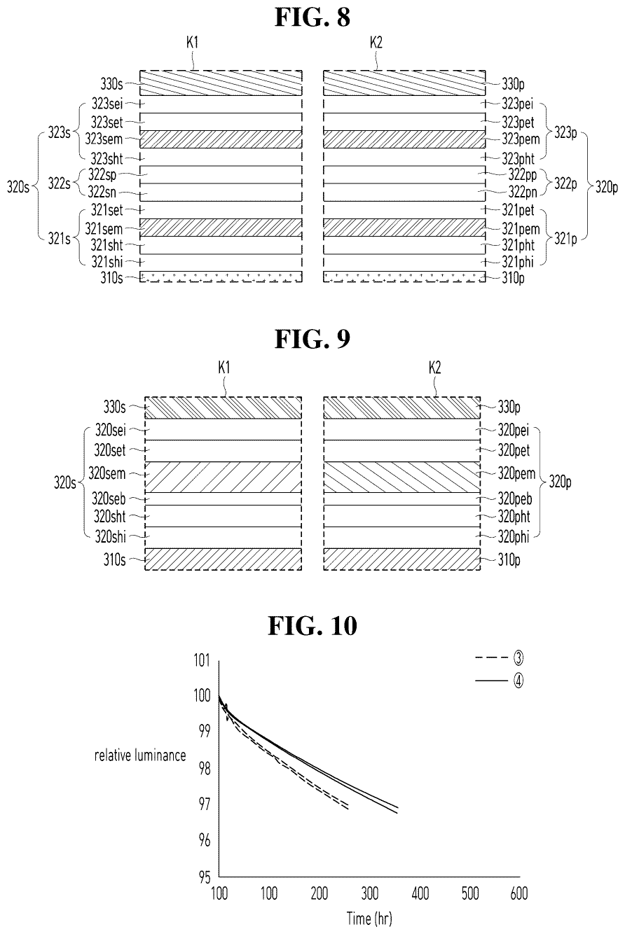

The display apparatus according to the embodiment of the present disclosure is described that the first light-emitting unit 320s of each sub-pixel SP includes a single first emission material layer 320sem, and the second light-emitting unit 320p of each sub-pixel SP includes a single second emission material layer 320pem. However, in the display apparatus according to another embodiment of the present disclosure, each of the first light-emitting unit 320s and the second light-emitting unit 320p can include a plurality of emission material layers 320sem and 320pem. For example, in the display apparatus according to another embodiment of the present disclosure, the first light-emitting unit 320s of each sub-pixel SP can include a first charge generation layer 322s disposed between a first lower emission stack 321s and a first upper emission stack 323s, the second light-emitting unit 320p of each sub-pixel SP can include a second charge generation layer 322p disposed between a second lower emission stack 321p and a second upper emission stack 323p, and each of the first lower emission stack 321s, the first upper emission stack 321p, the second lower emission stack 323s and the second upper emission stack 323p can include a single emission material layer 321sem, 321pem, 323sem and 323pem, as shown in FIG. 8.

The first lower emission stack 321s can be disposed close to the first lower electrode 310s. For example, the first lower emission stack 321s can include a first lower hole injection layer 321shi, a first lower hole transport layer 321sht, a first lower emission material layer 321sem and a first lower electron transport layer 321set, which are sequentially stacked on the upper surface of the first lower electrode 310s toward the first charge generation layer 322s. The first upper emission stack 323s can be disposed between the first charge generation layer 322s and the first upper electrode 330s. For example, the first upper emission stack 323s can include a first upper hole transport layer 323sht, a first upper emission material layer 323sem, a first upper electron transport layer 323set and a first upper electron injection layer 323sei, which are sequentially stacked on an upper surface of the first charge generation layer 322s toward the first upper electrode 330s.

The second lower emission stack 321p can be disposed close to the second lower electrode 310p. For example, the second lower emission stack 321p can include a second lower hole injection layer 321phi, a second lower hole transport layer 321pht, a second lower emission material layer 321pem and a second lower electron transport layer 321pet, which are sequentially stacked on the upper surface of the second lower electrode 310p toward the second charge generation layer 322p. The second upper emission stack 323p can be disposed between the second charge generation layer 322p and the second upper electrode 330p. For example, the second upper emission stack 323p can include a second upper hole transport layer 323pht, a second upper emission material layer 323pem, a second upper electron transport layer 323pet and a second upper electron injection layer 323pei, which are sequentially stacked on an upper surface of the second charge generation layer 322p toward the second upper electrode 330p.

The first charge generation layer 322s and the second charge generation layer 322p can provide holes or electrons to adjacent emission stack 321s, 323s, 321p and 323p. For example, each of the first charge generation layer 322s and the second charge generation layer 322p can have a stacked structure of a n-type charge generation layer 322sn and 322pn, and a p-type charge generation layer 322sp and 322pp. The first lower emission stack 321s can be disposed between the first lower electrode 310s and the n-type charge generation layer 322sn of the first charge generation layer 322s, and the first upper emission stack 323s can be disposed between the p-type charge generation layer 322sp of the first charge generation layer 322s and the first upper electrode 330s. The second lower emission stack 321p can be disposed between the second lower electrode 310p and the n-type charge generation layer 322pn of the second charge generation layer 322p, and the second upper emission stack 323p can be disposed between the p-type charge generation layer 322pp of the second charge generation layer 322p and the second upper electrode 330p. Thus, in the display apparatus according to another embodiment of the present disclosure, light can be emitted from the emission material layer 321sem, 321pem, 323sem and 323pem of each emission stack 321s, 321p, 323s and 323p.

The first upper emission material layer 323sem can include a same dopant as the first lower emission material layer 321sem, and the second upper emission material layer 323pem can include a same dopant as the second lower emission material 321pem. For example, the first lower emission material layer 321sem and the first upper emission material layer 323sem of each green sub-pixel G-SP can include a fluorescent dopant, and the second lower emission material layer 321pem and the second upper emission material layer 323pem of each green sub-pixel G-SP can include a phosphorescent dopant. Thus, in the display apparatus according to another embodiment of the present disclosure, the degree of freedom in the configuration of the first light-emitting unit 320s and the second light-emitting unit 320p formed in each sub-pixel SP can be improved.

The display apparatus according to the embodiment of the present disclosure is described that the first emission material layer 320sem and the second emission material layer 320pem of each sub-pixel SP include different dopants. However, in the display apparatus according to another embodiment of the present disclosure, the second light-emitting unit 320p of each sub-pixel SP can have a stacked structure same as the first light-emitting unit 320s of the corresponding sub-pixel SP, and at least one of layers constituting the second light-emitting unit 320p can have a composition ratio different from the corresponding layer of the first light-emitting unit 320s. For example, in the display apparatus according to another embodiment of the present disclosure, the first light-emitting unit 320s of each blue sub-pixel B-SP can include a first electron blocking layer 320seb disposed between the first hole transport layer 320sht and the first emission material layer 320sem, the second light-emitting unit 320p of each blue sub-pixel B-SP can include a second electron blocking layer 320peb disposed between the second hole transport layer 320pht and the second emission material layer 320pem, and the content of p-type dopant contained in the second electron blocking layer 320peb can be greater than the content of p-type dopant contained in the first electron blocking layer 320seb, as shown in FIG. 9.

The second emission material layer 320pem can include a same dopant as the first emission material layer 320sem. A composition ratio of the second emission material layer 320pem can be a same as a composition ratio of the first emission material layer 320sem. For example, the second emission material layer 320pem can be formed simultaneously with the first emission material layer 320sem. The second emission material layer 320pem can have a same thickness as the first emission material layer 320sem.

The second electron blocking layer 320peb can be disposed on a same layer as the first electron blocking layer 320seb. For example, the first electron blocking layer 320seb can be in direct contact with a lower surface of the first emission material layer 320sem toward the first lower electrode 310s, and the second electron blocking layer 320peb can be in direct contact with a lower surface of the second emission material layer 320pem toward the second lower electrode 310p. The second electron blocking layer 320peb can be formed of a same material as the first electron blocking layer 320seb. For example, a thickness of the second electron blocking layer 320peb can a same as a thickness of the first electron blocking layer 320seb.

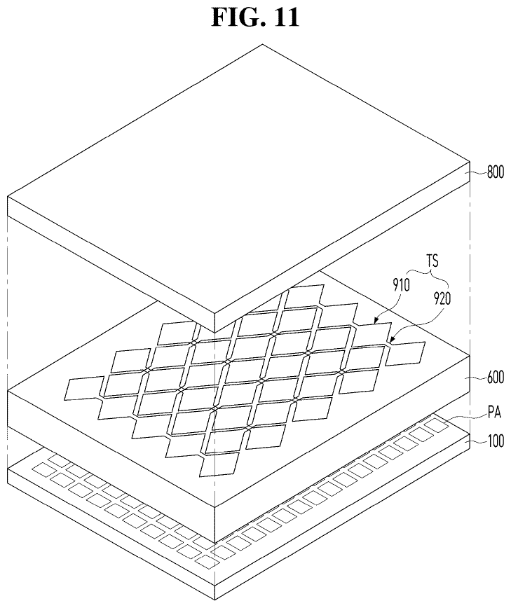

FIG. 10 is a graph showing simulation results for a relative luminance according to time of a first blue light \textcircled{3} emitted from a first blue light-emitting device including an electron blocking layer and a second blue light \textcircled{4} emitted from a second blue light-emitting device including an electron blocking layer having the content of p-type dopant greater than the first blue light-emitting device.

Referring to FIG. 10, a relative luminance of the second blue light \textcircled{4} according to time can be reduced slower than a relative luminance of the first blue light \textcircled{3} according to time. Thus, in the display apparatus according to another embodiment of the present disclosure, the second light-emitting device of each blue sub-pixel including the second electron blocking layer 320peb having a relative high the content of p-type dopant can have a longer lifespan than the first light-emitting device of each blue sub-pixel including the first electron blocking layer 320seb. That is, in the display apparatus according to another embodiment of the present disclosure, the lifespan of the second light-emitting device in each blue sub-pixel can be increased by the content of p-type dopant contained in the second electron blocking layer 320peb of the corresponding blue sub-pixel. Therefore, in the display apparatus according to another embodiment of the present disclosure, the variation in the quality between the first image and the second image due to the realization time can be minimized by various ways.

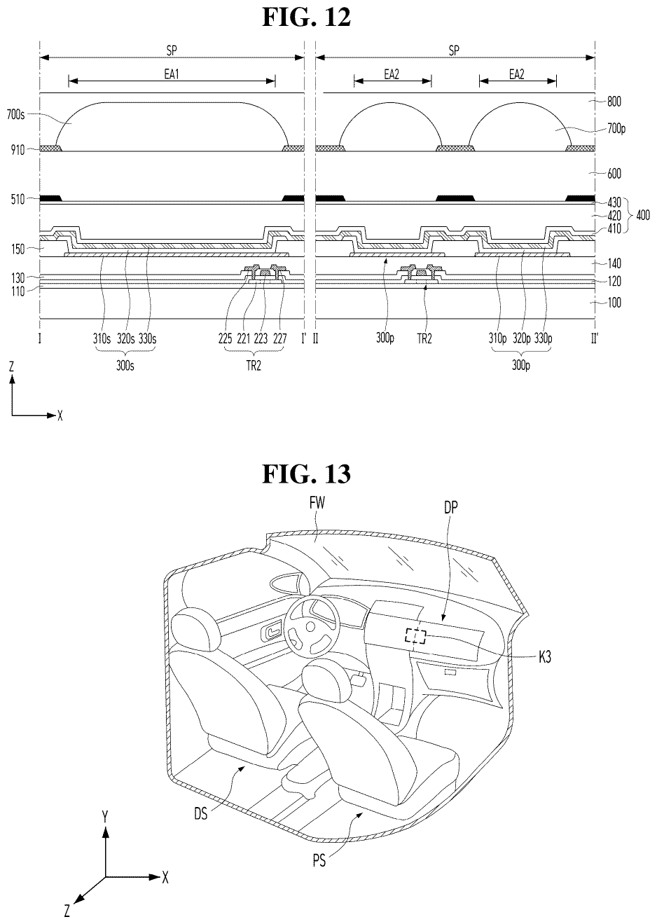

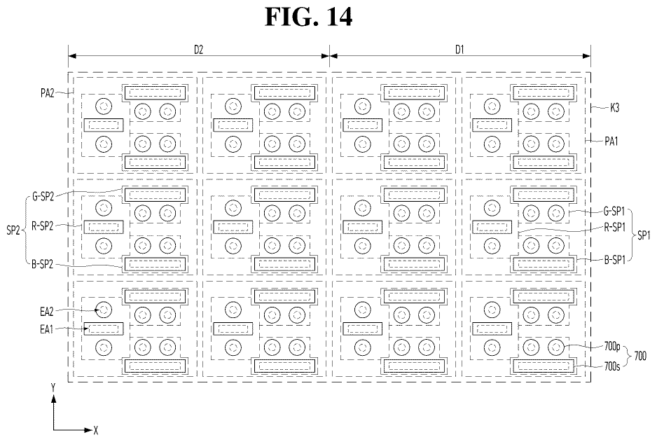

The display apparatus according to the embodiment of the present disclosure is described that the second barrier pattern 520 includes a same material as the first barrier pattern 510. However, in the display apparatus according to another embodiment of the present disclosure, the second barrier pattern 520 can include a different material from the first barrier pattern 510. For example, in the display apparatus according to another embodiment of the present disclosure, a touch sensor TS sensing a touch of the user and/or a tool can be disposed between the optical insulating layer 600 and the lens passivation layer 800, as shown in FIGS. 11 and 12.

The touch sensor TS can include touch electrodes 910 and bridge electrodes 920 connecting between the touch electrodes 910. The touch electrodes 910 and the bridge electrodes 920 can include a conductive material. The touch electrodes 910 and the bridge electrodes 920 can include a material capable of blocking light. For example, the touch electrodes 910 and the bridge electrodes 920 can include metal. At least some of the bridge electrodes 920 can include a different material from the touch electrodes 910. For example, at least some of the bridge electrodes 920 can be disposed on a different layer from the touch electrode 910.

A lower surface of each touch electrode 910 toward the device substrate 100 can be in direct contact with the upper surface of the optical insulating layer 600. The touch electrodes 910 can be disposed outside the emission areas EA1 and EA2 defined in each sub-pixel SP. For example, the touch electrodes 910 can be disposed within the non-emission area. The touch electrodes 910 can overlap the first barrier pattern 510. Thus, in the display apparatus according to another embodiment of the present disclosure, the first emission area EA1 and the second emission area EA2 of each sub-pixel SP can't overlap the touch electrodes 910. And, in the display apparatus according to another embodiment of the present disclosure, the touch electrodes 910 can limit a travelling direction of the light emitted from the emission areas EA1 and EA2 of each sub-pixel SP. For example, in the display apparatus according to another embodiment of the present disclosure, the touch electrodes 910 can function as the second barrier pattern. That is, in the display apparatus according to another embodiment of the present disclosure, a process of forming the second barrier pattern can be omitted. Therefore, in the display apparatus according to another embodiment of the present disclosure, the process efficiency can be improved.

The display apparatus according to the embodiment of the present disclosure is described that the display panel DP is installed in front of the passenger seat PS. However, in the display apparatus according to another embodiment of the present disclosure, the display panel DP can be installed in various locations. For example, in the display apparatus according to another embodiment of the present disclosure, the display panel DP can include a first display area D1 disposed in front of the passenger seat PS and a second display area D2 disposed between the driver seat DS and the passenger seat PS.

First pixel areas PA1 can be disposed within the first display area D1. Each of the first pixel areas PA1 can display various colors. For example, each of the first pixel areas PA1 can include first sub-pixels SP1. Each of the first sub-pixels SP1 can display a specific color. For example, each of the first sub-pixels SP1 can be one of a first red sub-pixel R-SP1, a first green sub-pixel G-SP1 and a firs blue sub-pixel B-SP1.

Second pixel areas PA2 can be disposed within the second display area D2. Each of the second pixel areas PA2 can display various colors. For example, each of the second pixel areas PA2 can include second sub-pixels SP2. Each of the second sub-pixels SP2 can display a specific color. Each of the second sub-pixels SP2 can have a same shape as each first sub-pixel SP1. For example, each of the first pixel area PA1 can include the first red sub-pixel R-SP1, the first green sub-pixel G-SP1 and the first blue sub-pixel B-SP1, and each of the second pixel area PA2 can include a second red sub-pixel R-SP2 disposed a region corresponding to the first red sub-pixel R-SP1, a second green sub-pixel G-SP1 disposed a region corresponding to the first green sub-pixel G-SP1 and a second blue sub-pixel B-SP1 disposed a region corresponding to the first blue sub-pixel B-SP1.

An image realized by the second display area D2 can be shared with the driver sitting in the driver seat DS and the passenger sitting in the passenger seat PS. An image realized by the first display area D1 cannot be recognized by the driver sitting in the driver seat DS, optionally. For example, the first emission area EA1 and the second emission area EA2 can be defined in each first sub-pixel SP1 and each second sub-pixel SP2, light emitted from the second emission area EA2 of each second sub-pixel SP2 can have same characteristics as light emitted from the first emission area EA1 of the corresponding second sub-pixel SP2, and light emitted from the second emission area EA2 of each first sub-pixel SP1 can have different characteristics from light emitted from the first emission area EA1 of the corresponding first sub-pixel SP1. Thus, in the display apparatus according to another embodiment of the present disclosure, the image realized by the first emission area EA1 of the first display area D1 can have substantially a same quality as the image realized by the second display area D2, and the decrease in the luminance of the image realized the second emission area EA2 of the first display area D2 according to realization time can be minimized. Therefore, in the display apparatus according to another embodiment of the present disclosure, the overall lifespan can be increased.

In the result, the display apparatus according to the embodiments of the present disclosure may comprise the first emission area and the second emission area, wherein the first light-emitting device and the first pixel lens can be disposed corresponding to the first emission area, wherein the second light-emitting device and the second pixel lens can be disposed corresponding to the second emission area, wherein the image realized by the second light-emitting device can have a viewing angle different from the image realized by the first light-emitting device, and wherein the light emitted from the second light-emitting device can have optical characteristics different from the light emitted from the first light-emitting device. Thus, in the display apparatus according to the embodiments of the present disclosure, the realization time of the second image can be different from the realization time of the first image due to the optionally driving of the first light-emitting device and the second light-emitting device, and the variation in the quality between the first image and the second image can be minimized by the difference in the optical characteristics between the first light-emitting device and the second light-emitting device. Thereby, in the display apparatus according to the embodiments of the present disclosure, the overall lifespan can be increased. And, in the display apparatus according to the embodiments of the present disclosure, the low power operation can be possible, and the power consumption can be reduced.

In one embodiment, a display apparatus comprises: a first light-emitting device on a first emission area of a device substrate; a second light-emitting device on a second emission area of the device substrate, the second light-emitting device emitting light of a same color as the light emitted by the first light-emitting device; a first pixel lens on the first light-emitting device, the first pixel lens having a planar shape corresponding to a planar shape of the first emission area; and a second pixel lens on the second light-emitting device, the second pixel lens having a planar shape corresponding a planar shape of the second emission area, wherein the planar shape of the second emission area is different from the planar shape of the first emission area, and wherein an electroluminescence spectrum of the light emitted by the second light-emitting device is different from an electroluminescence spectrum of the light emitted by the first light-emitting device.

In one embodiment, the electroluminescence spectrum of the light emitted by the second light-emitting device has a full width at half maximum (FWHM) that is different from the electroluminescence spectrum of the light emitted by the first light-emitting device.

In one embodiment, a maximum luminance of the light emitted by the second light-emitting device is different from a maximum luminance of the light emitted by the first light-emitting device.

In one embodiment, a peak wavelength in the electroluminescence spectrum of the light emitted by the second light-emitting device is different from a peak wavelength in the electroluminescence spectrum of the light emitted by the first light-emitting device.

In one embodiment, the first light-emitting device includes a first emission material layer between a first lower electrode and a first upper electrode and the second light-emitting device includes a second emission material layer between a second lower electrode and a second upper electrode, and wherein the second emission material layer of the second light-emitting device includes a second dopant that is different from a first dopant included in the first emission material layer of the first light-emitting device.

In one embodiment, the first dopant included in the first emission material layer of the first light-emitting device comprises a fluorescent dopant, and the second dopant included in the second emission material layer of the second light-emitting device comprises a phosphorescent dopant.

In one embodiment, the second lower electrode of the second light-emitting device has a stacked structure that is a same as the first lower electrode of the first light-emitting device, and wherein a material of the second upper electrode of the second light-emitting device is a same as a material of the first upper electrode of the first light-emitting device.

In one embodiment, the second pixel lens is on a same layer as the first pixel lens.

In one embodiment, a display apparatus comprises: a device substrate; a bank insulating layer on the device substrate, the bank insulating layer defining a first emission area and a second emission area in a sub-pixel; an optical insulating layer on the bank insulating layer, the optical insulating layer overlapping the first emission area and the second emission area; a first light-emitting device between the device substrate and the optical insulating layer in the first emission area, the first light-emitting device including a first light-emitting unit; a second light-emitting device between the device substrate and the optical insulating layer in the second emission area, the second light-emitting device including a second light-emitting unit; a first pixel lens on the optical insulating layer, the first pixel lens overlapping the first light-emitting device; and a second pixel lens on the optical insulating layer, the second pixel lens overlapping the second light-emitting device, wherein a planar shape of the second pixel lens is different from a planar shape of the first pixel lens, wherein a stacked structure of the second light-emitting unit is a same as a stacked structure of the first light-emitting unit, and wherein at least one layer of layers constituting the second light-emitting unit has a composition ratio that is different from a corresponding layer of the first light-emitting unit.

In one embodiment, a planar shape of the sub-pixel is a bar extending in a first direction, and wherein a cross-section of the second pixel lens in the first direction has a semi-circular shape.

In one embodiment, the first light-emitting unit includes a first emission material layer disposed between a first functional layer and a second functional layer and the second light-emitting unit includes a second emission material layer disposed between a third functional layer and a fourth functional layer, wherein the fourth functional layer of the second light-emitting unit has a composition ratio that is a same as the second functional layer of the first light-emitting unit, and wherein a content of p-type dopant contained in the third functional layer of the second light-emitting unit is different from a content of p-type dopant contained in the first functional layer of the first light-emitting unit.

In one embodiment, the third functional layer of the second light-emitting unit has a same thickness as the first functional layer of the first light-emitting unit.

In one embodiment, the first light-emitting device includes a first lower electrode and a first upper electrode having a smaller work-function than the first lower electrode, and the second light-emitting device includes a second lower electrode and a second upper electrode having a smaller work-function than the second lower electrode, wherein the first light-emitting unit is between the first lower electrode and the first upper electrode and the second light-emitting unit is between the second lower electrode and the second upper electrode, and wherein the first functional layer is in contact with a surface of the first emission material layer toward the first lower electrode and the third functional layer is in contact with a surface of the second emission material layer toward the second lower electrode.

In one embodiment, the second functional layer is in contact with a surface of the first emission material layer toward the first upper electrode, and wherein the fourth functional layer of the second light-emitting unit has a same thickness as the second functional layer of the first light-emitting unit.

In one embodiment, a number of second emission areas in the sub-pixel is different from a number of first emission areas in the sub-pixel.

In one embodiment, a display device comprises: a device substrate including a sub-pixel, the sub-pixel having a first emission area and a second emission area; a driving transistor; a first light-emitting device on the first emission area, the first light-emitting device connected to the driving transistor; a second light-emitting device on the second emission area and connected to the driving transistor, the second light-emitting device emitting light of a same color of light emitted by the first light-emitting device but having an electroluminescence spectrum that is different from an electroluminescence spectrum of the light emitted by the first light-emitting device; a first pixel lens overlapping the first light-emitting device in the first emission area; and a second pixel lens overlapping the second light-emitting device in the second emission area, wherein the display device displays an image having a first viewing angle during a first mode during which the first light-emitting device emits the light through the first pixel lens, and the display device displays an image having a second viewing angle that is different from the first viewing angle during a second mode during which the second light-emitting device emits the light through the second pixel lens.

In one embodiment, the display device according to claim 16, further comprising: a first control transistor connected to the driving transistor; a second control transistor connected to the driving transistor, wherein the first control transistor is turned on in response to a first control signal and the second control transistor is turned off during the first mode, and the second control transistor is turned on in response to a second control signal and the first control transistor is turned off during the second mode.

In one embodiment, the display device according to claim 16, the first pixel lens has a planar shape corresponding to a planar shape of the first emission area and the second pixel lens has a planar shape corresponding a planar shape of the second emission area.

In one embodiment, the display device according to claim 18, wherein the planar shape of the first pixel lens is different from the planar shape of the second pixel lens.

In one embodiment, the display device of claim 16, wherein the first light-emitting device includes a first emission material having a first dopant and the second light-emitting device includes a second emission material layer having a second dopant that is different from the first dopant.

What is claimed is:

1. A display apparatus comprising:
a first light-emitting device on a first emission area of a device substrate;
a second light-emitting device on a second emission area of the device substrate, the second light-emitting device emitting light of a same color as the light emitted by the first light-emitting device;
a first pixel lens on the first light-emitting device, the first pixel lens having a planar shape corresponding to a planar shape of the first emission area; and
a second pixel lens on the second light-emitting device, the second pixel lens having a planar shape corresponding a planar shape of the second emission area,
wherein the planar shape of the second emission area is different from the planar shape of the first emission area, and
wherein an electroluminescence spectrum of the light emitted by the second light-emitting device is different from an electroluminescence spectrum of the light emitted by the first light-emitting device.

2. The display apparatus according to claim 1, wherein the electroluminescence spectrum of the light emitted by the second light-emitting device has a full width at half maximum (FWHM) that is different from the electroluminescence spectrum of the light emitted by the first light-emitting device.

3. The display apparatus according to claim 1, wherein a maximum luminance of the light emitted by the second light-emitting device is different from a maximum luminance of the light emitted by the first light-emitting device.

4. The display apparatus according to claim 1, wherein a peak wavelength in the electroluminescence spectrum of the light emitted by the second light-emitting device is different from a peak wavelength in the electroluminescence spectrum of the light emitted by the first light-emitting device.

5. The display apparatus according to claim 1, wherein the first light-emitting device includes a first emission material layer between a first lower electrode and a first upper electrode and the second light-emitting device includes a second emission material layer between a second lower electrode and a second upper electrode, and
wherein the second emission material layer of the second light-emitting device includes a second dopant that is different from a first dopant included in the first emission material layer of the first light-emitting device.

6. The display apparatus according to claim 5, wherein the first dopant included in the first emission material layer of the first light-emitting device comprises a fluorescent dopant, and the second dopant included in the second emission material layer of the second light-emitting device comprises a phosphorescent dopant.

7. The display apparatus according to claim 5, wherein the second lower electrode of the second light-emitting device has a stacked structure that is a same as the first lower electrode of the first light-emitting device, and
wherein a material of the second upper electrode of the second light-emitting device is a same as a material of the first upper electrode of the first light-emitting device.

8. The display apparatus according to claim 1, wherein the second pixel lens is on a same layer as the first pixel lens.

9. A display apparatus, comprising:
a device substrate;
a bank insulating layer on the device substrate, the bank insulating layer defining a first emission area and a second emission area in a sub-pixel;
an optical insulating layer on the bank insulating layer, the optical insulating layer overlapping the first emission area and the second emission area;
a first light-emitting device between the device substrate and the optical insulating layer in the first emission area, the first light-emitting device including a first light-emitting unit;
a second light-emitting device between the device substrate and the optical insulating layer in the second emission area, the second light-emitting device including a second light-emitting unit;
a first pixel lens on the optical insulating layer, the first pixel lens overlapping the first light-emitting device; and
a second pixel lens on the optical insulating layer, the second pixel lens overlapping the second light-emitting device,
wherein a planar shape of the second pixel lens is different from a planar shape of the first pixel lens,
wherein a stacked structure of the second light-emitting unit is a same as a stacked structure of the first light-emitting unit, and
wherein at least one layer of layers constituting the second light-emitting unit has a composition ratio that is different from a corresponding layer of the first light-emitting unit.

10. The display apparatus according to claim 9, wherein a planar shape of the first pixel lens is a bar extending in a first direction, and
wherein a cross-section of the second pixel lens in the first direction has a semi-circular shape.

11. The display apparatus according to claim 9, wherein the first light-emitting unit includes a first emission material layer disposed between a first functional layer and a second functional layer and the second light-emitting unit includes a second emission material layer disposed between a third functional layer and a fourth functional layer,
wherein the fourth functional layer of the second light-emitting unit has a composition ratio that is a same as the second functional layer of the first light-emitting unit, and
wherein a content of p-type dopant contained in the third functional layer of the second light-emitting unit is different from a content of p-type dopant contained in the first functional layer of the first light-emitting unit.

12. The display apparatus according to claim 11, wherein the third functional layer of the second light-emitting unit has a same thickness as the first functional layer of the first light-emitting unit.

13. The display apparatus according to claim 11, wherein the first light-emitting device includes a first lower electrode and a first upper electrode having a smaller work-function than the first lower electrode, and the second light-emitting device includes a second lower electrode and a second upper electrode having a smaller work-function than the second lower electrode,
wherein the first light-emitting unit is between the first lower electrode and the first upper electrode and the second light-emitting unit is between the second lower electrode and the second upper electrode, and
wherein the first functional layer is in contact with a surface of the first emission material layer toward the first lower electrode and the third functional layer is in contact with a surface of the second emission material layer toward the second lower electrode.

14. The display apparatus according to claim 13, wherein the second functional layer is in contact with a surface of the first emission material layer toward the first upper electrode, and
wherein the fourth functional layer of the second light-emitting unit has a same thickness as the second functional layer of the first light-emitting unit.

15. The display apparatus according to claim 9, wherein a number of second emission areas in the sub-pixel is different from a number of first emission areas in the sub-pixel.

16. A display device comprising:
a device substrate including a sub-pixel, the sub-pixel having a first emission area and a second emission area;
a driving transistor;
a first light-emitting device on the first emission area, the first light-emitting device connected to the driving transistor;
a second light-emitting device on the second emission area and connected to the driving transistor, the second light-emitting device emitting light of a same color of light emitted by the first light-emitting device but having an electroluminescence spectrum that is different from an electroluminescence spectrum of the light emitted by the first light-emitting device;
a first pixel lens overlapping the first light-emitting device in the first emission area; and
a second pixel lens overlapping the second light-emitting device in the second emission area,
wherein the display device displays an image having a first viewing angle during a first mode during which the first light-emitting device emits the light through the first pixel lens, and the display device displays an image having a second viewing angle that is different from the first viewing angle during a second mode during which the second light-emitting device emits the light through the second pixel lens.

17. The display device according to claim 16, further comprising:
a first control transistor connected to the driving transistor;
a second control transistor connected to the driving transistor,
wherein the first control transistor is turned on in response to a first control signal and the second control transistor is turned off during the first mode, and the second control transistor is turned on in response to a second control signal and the first control transistor is turned off during the second mode.

18. The display device according to claim 16, wherein the first light-emitting device includes a first lower electrode, a first functional layer, a first emission material layer and a first upper electrode,
wherein the second light-emitting device includes a second lower electrode, a second functional layer, a second emission material layer and a second upper electrode, and
wherein a content of p-type dopant contained in the second functional layer of the second light-emitting device is different from the a content of p-type dopant contained in the first functional layer of the first light-emitting device.

19. The display device according to claim 18, wherein the second functional layer is disposed on a same layer as the first functional layer.

20. The display device of claim 18, wherein the first light-emitting device further includes a first hole transport layer between the first lower electrode and the first function layer, and
wherein the second light-emitting device further includes a second hole transport layer between the second lower electrode and the second function layer.
